(19) United States
(12) Patent Application Publication
(10) Pub. No.: US 2017/0256517 A1
(43) Pub. Date: Sep. 7, 2017

(54) SILVER BONDING WIRE AND METHOD OF MANUFACTURING THE SAME

(71) Applicant: Heraeus Deutschland GmbH & Co. KG, Hanau (DE)

(72) Inventors: Ki Ho KIM, Namyangju-si, Gyeonggi-do (KR); Yong-Deok TARK, Namdong-gu, Incheon (KR); Il Tae KANG, Kunsan (KR); Byoung Gil KIM, Incheon (KR); Tae Yeop KIM, Seoul (KR)

(21) Appl. No.: 15/506,511

(22) PCT Filed: Jun. 29, 2015
(86) PCT No.: PCT/EP2015/064672

§ 371 Date: Feb. 24, 2017

(30) Foreign Application Priority Data
Aug. 27, 2014 (KR) 10-2014-0112599

(51) Int. Cl. H01L 23/00; H01B 1/02

(52) U.S. Cl. CPC H01L 24/43; H01L 24/45; H01L 24/48; H01L 24/78; H01B 1/02; H01L 2224/43848; H01L 2224/45015; H01L 2224/45139

(57) ABSTRACT

A bonding wire and a method of manufacturing the bonding wire are provided. The bonding wire contains 90.0 to 99.0 wt % of silver (Ag); 0.2 to 2.0 wt % of gold (Au); 0.2 to 4.0 wt % of palladium (Pd), platinum (Pt), rhodium (Rh), or a combination thereof; 10 to 1000 ppm of dopants; and inevitable impurities. In the wire, the ratio of (a)/(b) is 3 to 5, in which (a) represents the amount of crystal grains having <100> orientation in crystalline orientations <hkl> in a wire lengthwise direction and (b) represents the amount of crystal grains having <111> orientation in crystalline orientations <hkl> in the wire lengthwise direction.

### BACKGROUND OF THE INVENTION

(a) Field of the Invention

One embodiment of the present invention relates to a bonding wire having an improved characteristic.

Further, another embodiment of the present invention relates to a microelectronic component having the bonding wire according to the one embodiment of the present invention and/or a method of manufacturing the bonding wire according to the one embodiment of the present invention.

(b) Description of the Related Art

A bonding wire is used in a process of manufacturing a semiconductor device in order to electrically connect an integrated circuit to a printed circuit board in manufacturing the semiconductor device. Further, the bonding wire is used in order to electrically connect a transistor and a diode to a pin or a pad of a housing in a power electronic application. The bonding wire is initially manufactured using gold, and is currently manufactured using a low-priced material such as silver. The silver wire has very favorable electrical conductivity and thermal conductivity, but bonding of the silver wire has problems itself.

In the present invention, the term of the bonding wire embraces all cross section shapes and all typical wire diameters. However, a bonding wire having a circular cross section and a short diameter is preferably used.

Since silver is cheaper than gold, recent several researches and developments aim for a bonding wire having a core material using silver as a main composite. However, it is necessary to further improve the bonding wire itself and a bonding wire technology of a bonding process.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide an improved bonding wire.

Further, the present invention has been made in an effort to provide a bonding wire having advantages of reducing cost by having favorable processability and having no difficulty in being mutually connected.

Furthermore, the present invention has been made in an effort to provide a bonding wire having advantages of exhibiting excellent bondability.

Moreover, the present invention has been made in an effort to provide a bonding wire having advantages of exhibiting an improved looping characteristic.

In addition, the present invention has been made in an effort to provide a bonding wire having advantages of solving sticky between wires.

An exemplary embodiment of the present invention provides a bonding wire including 90.0 to 99.0 wt % of silver (Ag); 0.2 to 2.0 wt % of gold (Au); 0.2 to 4.0 wt % of palladium (Pd), platinum (Pt) or rhodium (Rh), or a combination thereof; 10 to 1000 ppm of dopants; and inevitable impurities, in which a ratio of (a)/(b) is 3 to 5.

Here, the (a) refers to the amount of crystal grains having <100> orientation in crystalline orientations <hkl> in a wire lengthwise direction, and the (b) refers to the amount of crystal grains having <111> orientation in crystalline orientations <hkl> in the wire lengthwise direction.

The bonding wire of anyone of the embodiments, wherein:

the dopants may be calcium (Ca).

The bonding wire of anyone of the embodiments, wherein:

the dopants may be calcium, a content of the calcium may be 10 to 100 ppm.

The bonding wire of anyone of the embodiments, wherein:

the number of twin grain boundaries of the bonding wire may be 4 to 14%.

The bonding wire of anyone of the embodiments, wherein:

a ratio of (b)/(c) of the bonding wire may be 1.5 to 8.

Here, the (b) refers to the amount of the crystal grains having <111> orientation in crystalline orientations <hkl> in a wire lengthwise direction, and the (c) refers to a Taylor factor.

The bonding wire of anyone of the embodiments, wherein:

an average size of the crystal grains in the longitudinal direction may be 0.8 to 1.2 μm.

The bonding wire of anyone of the embodiments, wherein:

the wire may be exposed in an intermediate annealing step before a final drawing step of the wire.

The bonding wire of anyone of the embodiments, wherein:

the intermediate annealing step may be performed one to three times.

The bonding wire of anyone of the embodiments, wherein:

the intermediate annealing step may be performed two to three times.

The bonding wire of anyone of the embodiments, wherein:

the intermediate annealing step may include a first batch intermediate annealing step; a second continuous intermediate annealing step; and/or a third continuous intermediate annealing step.

The bonding wire of anyone of the embodiments, wherein:

the first intermediate annealing step may be performed for 50 to 150 minutes at 400 to 800° C., and may include a step of cooling the wire for 50 to 150 minutes.

The bonding wire of anyone of the embodiments, wherein:

the second intermediate annealing step may be performed at 400 to 800° C. under a speed of 100 to 300 rpm.

The bonding wire of anyone of the embodiments, wherein:

the third intermediate annealing step may be performed at 400 to 800° C. under a speed of 100 to 300 rpm.

The bonding wire of anyone of the embodiments, wherein:

the wire may be exposed in a casting step by a vertical continuous casting method, and the vertical continuous casting method may be performed at 1150 to 1350° C.

The bonding wire of anyone of the embodiments, wherein:

the vertical continuous casting method may be performed under a casting speed of 4 to 9 cm/min.

Another exemplary embodiment of the present invention provides a microelectronic component package including an electronic device and a substrate that are connected to each other by the bonding wire according to the one embodiment of the present invention, as mentioned above.

Yet another exemplary embodiment of the present invention provides a method of manufacturing a bonding wire including providing a wire raw material; casting the wire raw material by a vertical continuous casting method; drawing the cast wire in sequence until reaching a final diameter; and annealing the drawn wire, in which an intermediate annealing step is performed one to three before the final drawing step of the wire, and the wire raw material includes 90.0 to 99.0 wt % of silver (Ag); 0.2 to 2.0 wt % of gold (Au); 0.2 to 4.0 wt % of palladium (Pd), platinum (Pt) or rhodium(Rh), or a combination thereof; 10 to 1000 ppm of dopants; and inevitable impurities.

The method of manufacturing a bonding wire of anyone of the embodiments, wherein:

the dopants may be calcium, and a content of the calcium may be 10 to 100 ppm.

The method of manufacturing a bonding wire of anyone of the embodiments, wherein:

the intermediate annealing step may include a first batch intermediate annealing step; a second continuous intermediate annealing step; and/or a third continuous intermediate annealing step.

The method of manufacturing a bonding wire of anyone of the embodiments, wherein:

the first intermediate annealing step may be performed for 50 to 150 minutes at 400 to 800° C., and includes a step of cooling the wire for 50 to 150 minutes.

The method of manufacturing a bonding wire of anyone of the embodiments, wherein:

the second intermediate annealing step may be performed at 400 to 800° C. under a speed of 100 to 300 rpm.

The method of manufacturing a bonding wire of anyone of the embodiments, wherein:

the third intermediate annealing step may be performed at 400 to 800° C. under a speed of 100 to 300 rpm.

The method of manufacturing a bonding wire of anyone of the embodiments, wherein:

in the casting of the wire raw material by the vertical continuous casting method, the vertical continuous casting method may be performed at 1150 to 1350° C.

The method of manufacturing a bonding wire of anyone of the embodiments, wherein:

the vertical continuous casting method may be performed under a casting speed of 4 to 9 cm/min.

The method of manufacturing a bonding wire of anyone of the embodiments, wherein:

a ratio of (a)/(b) of the bonding wire manufactured by the method may be 3 to 5.

Here, the (a) refers to the amount of crystal grains having <100> orientation in crystalline orientations <hkl> in a wire lengthwise direction, and the (b) refers to the amount of crystal grains having <111> orientation in crystalline orientations <hkl> in the wire lengthwise direction.

The method of manufacturing a bonding wire of anyone of the embodiments, wherein:

the number of twin grain boundaries of the bonding wire manufactured by the method may be 4 to 14%.

The method of manufacturing a bonding wire of anyone of the embodiments, wherein:

a ratio of (b)/(c) of the bonding wire manufactured by the method may be 1.5 to 8.

Here, the (b) refers to the amount of crystal grains having <111> orientation in crystalline orientations <hkl> in a wire lengthwise direction, and the (c) refers to a Taylor factor.

The method of manufacturing a bonding wire of anyone of the embodiments, wherein:

an average size of crystal grains of the bonding wire manufactured by the method in a longitudinal direction may be 0.8 to 1.2 μm.

The method of manufacturing a bonding wire of anyone of the embodiments, wherein:

the bonding wire manufactured by the method may be the bonding wires according to the various embodiments of the present invention.

According to one embodiment of the present invention, it is possible to provide a bonding wire capable of reducing manufacturing cost by having favorable processability and having no necessity of being mutually connected.

Further, it is possible to provide a bonding wire having an improved boding characteristic.

Moreover, it is possible to provide a bonding wire having an improved looping characteristic.

In addition, it is possible to provide a bonding wire capable of solving sticky between wires.

### BRIEF DESCRIPTION OF THE DRAWINGS

FIG. 1 illustrates data obtained by evaluating a looping characteristic of a bonding wire according to an exemplary embodiment of the present invention.

FIG. 2 illustrates photographs obtained by evaluating a bonding characteristic of the bonding wire according to the exemplary embodiment of the present invention.

### DETAILED DESCRIPTION OF THE EMBODIMENTS

Hereinafter, embodiments of the present invention will be described in detail. These embodiments are presented by way of example only, and are not intended to limit the present invention. Indeed, the present invention is defined only by the category of the appended claims.

It is found out that a wire according to one embodiment of the present invention solves one or more of the aforementioned objects. Furthermore, it is found out that a method of manufacturing the wire overcomes one or more of problems in manufacturing the wire. Moreover, it is found out that a system including the wire of the present invention is more reliable on an interface between another electrical element and the wire according to the present invention.

One or more of the objects of the one embodiment of the present invention are achieved by the subject matter of independent claim. Dependent claims of the independent claim represent preferred aspects of the present invention, and one or more of the aforementioned objects are also achieved by the subject matter of the dependent claims.

In one embodiment of the present invention, there is provided a bonding wire including 90.0 to 99.0 wt % of silver (Ag); 0.2 to 2.0 wt % of gold (Au); 0.2 to 4.0 wt % of palladium (Pd), platinum (Pt) or rhodium (Rh), or a combination thereof; 10 to 1000 ppm of dopants; and inevitable impurities, in which a ratio of (a)/(b) is 3 to 5.

The (a) refers to the amount of crystal grains having <100> orientation in crystalline orientations <hkl> in a wire lengthwise direction, and the (b) refers to the amount of crystal grains having <111> orientation in crystalline orientations <hkl> in the wire lengthwise direction.

Here, all contents or shares of the composites are represented as weight-based shares. Particularly, a composite share represented as a percentage unit refers to wt %, and a composite share represented as a ppm (parts per million) unit refers to weight-ppm. A percentage value related to a crystal grain having a predetermined size and/or orientation refers to a share of a total particle number.

In order to determine the grain size and/or the grain orientation, a wire sample is manufactured, and the manufactured wire is measured using EBSD (Electron Backscatter Diffraction) and is evaluated. Hereinafter, accurate definitions of claimed features of the present invention will refer to description for exemplary embodiments of the present invention.

When a share of any composite is larger than those of all other composites of a reference material, the composite is a “main composite.”

Preferably, the main composite includes 50 to 100% of the total weight of the material.

In a preferred embodiment, the wire includes silver as the main composite.

When a ratio of the (a)/(b) is at least 3 to 5, since the constant amount of grains is large, it is possible to reduce changes in mechanical and electrical characteristics of the bonding wire and a characteristic according to a product.

More specifically, the dopants may be calcium (Ca).

A content of the calcium may be 10 to 100 ppm. It is possible to control a sway and/or snake phenomenon of the wire by using the calcium dopants. The present invention is not restricted by such a range, and an appropriate content may be selected depending on a required characteristic.

More specifically, a ratio of (b)/(c) of the bonding wire may be 1.5 to 8.

The (b) refers to the amount of crystal grains having <111> orientation in crystalline orientations <hkl> in a wire lengthwise direction, and the (c) refers to a Taylor factor.

The Taylor factor is a factor for describing a relation between a deformation behavior of each grain and a direction of the grain, and a bonding characteristic can be improved when the factor satisfies a ratio range of the (b)/(c).

More specifically, the number of twin grain boundaries of the bonding wire may be 4 to 14%. When the number of twin grain boundaries satisfies such a range, it is possible to reduce an electrical characteristic deterioration affected by the number of twin grain boundaries.

More specifically, an average size of the crystal grains in the longitudinal direction may be 0.8 to 1.2 μm.

Sizes of the crystal grains are particularly homogeneous, and contribute to favorable reproducibility of a wire property.

In the most advantageous embodiment, the standard deviation of the sizes of the crystal grains may be 0.1 to 0.5 μm. More preferably, the standard deviation of the sizes of the crystal grains may be 0.1 to 0.4 μm, or 0.1 μm to 0.25 μm. It is found out that quality of the wire and the reproducibility thereof are remarkably increased when the sizes of the crystal grains are particularly homogeneous.

In general, additional structures of the grain such as the grain size and orientation can be adjusted by appropriately selecting known manufacturing parameters. The manufacturing parameters are other parameters such as the number of drawing steps and reductions in diameters, including annealing parameters such as an annealing temperature and an exposing time.

In one preferred embodiment of the present invention, the wire may be exposed in an intermediate annealing step before a final drawing step. The intermediate annealing means that the annealing is performed before a step of affecting a microstructure of the wire.

The intermediate annealing step may be performed one to three times. It is possible to improve a sticky characteristic of the wire by the three intermediate annealing steps.

More specifically, the intermediate annealing step may include a first batch intermediate annealing step; a second continuous intermediate annealing step; and/or a third continuous intermediate annealing step.

For specific example, the first intermediate annealing step may be performed for 50 to 150 minutes at 400 to 800° C., and may include a step of cooling the wire for 50 to 150 minutes.

For specific example, the second intermediate annealing step may be performed at 400 to 800° C. under a speed of 100 to 300 rpm.

For specific example, the third intermediate annealing step may be performed at 400 to 800° C. under a speed of 100 to 300 rpm.

A process condition of the intermediate annealing step may be results obtained through a plurality of repeated experiments, and may affect the characteristic of the bonding wire.

It should be understood that exposing the wire in the annealing step before using the wire in the bonding process is generally the intermediate annealing step or the final annealing step. The final annealing step is a final step of the wire manufacturing process of affecting the wire microstructure. Parameters of the final annealing step are well known in the art.

When the wire is exposed in the final annealing step, the intermediate annealing step is the most preferably performed in advance, and this means that two to three of different annealing steps are performed in the wire manufacturing process. As in the drawing step, a process of affecting the microstructure of the wire may be performed between the intermediate annealing step and the final annealing step. This process can particularly optimize the crystal structure of the wire of the present invention.

The wire may be exposed in a casting step by a vertical continuous casting method, and the vertical continuous casting method may be performed at 1150 to 1350° C.

The vertical continuous casting method is a method of primarily casting a wire raw material and is well known in the art. It is possible to control a casting temperature range to 1150 to 1350° C. in such a step. In this case, it is possible to solve problems such as an apple bite ball and a snake skin caused when forming FAB of the bonding wire. Furthermore, it is possible to reduce an OCB (Off Centered Ball) occurrence among bonding characteristics of the wire.

More specifically, the vertical continuous casting method may be performed under a casting speed of 4 to 9 cm/min. In such a case, it is possible to obtain a dendrite structure denser than an existing cast structure, and such a uniform and dense structure can improve the bonding characteristic.

Particularly, one embodiment of the present invention relates to a thin bonding wire. An observed effect is to particularly have an advantage in controlling the grain size and the grain orientation of the thin wire. In this case, the term of “thin wire” is defined as a wire having a diameter in a range of 8 μm to 80 μm. More preferably, the thin wire according to the present invention has a diameter of 14 to 25 μm. In the thin wire, the composites and the annealing process of the present invention are particularly helpful to obtain advantageous properties.

Although not mandatory, most thin wires have essentially circular cross-sectional views. In context of the present invention, the term of “cross-sectional view” means an incision surface of the wire, and the incision surface thereof is perpendicular to an extension line in the longitudinal direction of the wire. The cross-sectional view can be seen at an arbitrary position on the extension line in the longitudinal direction of the wire. The “longest path” through the wire in a cross section is the longest chord that can be placed through the cross section of the wire on a plane of the cross-sectional view. The “shortest path” through the wire in the cross section is the longest chord perpendicular to the longest path on the plane of the cross-sectional view defined above. When the wire has a perfect circular cross section, the longest path and the shortest path are not distinguished, and share the same value. The term of “diameter” is an arithmetic mean of all geometric diameters on an arbitrary plane and in an arbitrary direction, and the all planes are perpendicular to the extension line in the longitudinal direction of the wire.

Another embodiment of the present invention relates to a microelectronic component including an electronic device and a substrate that are connected to each other by the bonding wire according to the one embodiment of the present invention.

The bonding wire according to the one embodiment of the present invention is applicable to various component packages, and the characteristic of the wire can be partially controlled depending on characteristics of required components.

In yet another embodiment of the present invention, there is provided a method of manufacturing a bonding wire. The method includes providing a wire raw material; casting the wire raw material by a vertical continuous casting method; drawing the cast wire in sequence until reaching a final diameter; and annealing the drawn wire for a minimum annealing time at a lowest annealing temperature. An intermediate annealing step is performed one to three times before the final drawing step of the wire, and the wire raw material includes 90.0 to 99.0 wt % of silver (Ag); 0.2 to 2.0 wt % of gold (Au); 0.2 to 4.0 wt % of palladium (Pd), platinum (Pt) or rhodium (Rh), or a combination thereof; 10 to 1000 ppm of dopants; and inevitable impurities.

It should be understood that the drawing of the raw material may be performed in various steps. It should be understood that the wire raw material has the composites of the wire according to the one embodiment of the present invention. It is possible to simply obtain the wire raw material by using a homogeneous mixture formed by melting a limited amount of silver and adding limited amounts of additional composites. Thereafter, the wire raw material may be cast or moulded using a molten alloy or a solidified alloy by an arbitrary known method.

The description for the dopants of the wire raw material is already presented when the wire according to the one embodiment of the present invention is described, and, thus, the description thereof will not be presented.

In the one preferred embodiment of the present invention, in the method, the intermediate annealing step may be performed one to three times before the final drawing step of the wire.

In the additional intermediate annealing step, the crystal structure is optimized before intense mechanical deformation is caused in the drawing step of the wire. It is found out that the intermediate annealing is advantageous in finally obtaining the microstructure of the wire. For example, the intermediate annealing step is helpful to reduce the deviation of the grain sizes in the final product and to improve the orientation of the grain. The parameters of the intermediate annealing may be adjusted to be appropriate for required wire parameters.

The description for the intermediate annealing is as mentioned above.

Moreover, the description for the vertical continuous casting method is as mentioned above.

A more preferred specific embodiment of the method of manufacturing the wire refers to the description for the wire of the present invention in connection with optimized annealing parameters.

Hereinafter, a preferred exemplary embodiment of the present invention and a comparative example are described. However, the following exemplary embodiment is merely a preferred exemplary embodiment of the present invention, and is not intended to limit the present invention.

### Exemplary Embodiment

The present invention is more specifically exemplified by the exemplary embodiment. The exemplary embodiment presents an exemplary description of the present invention, and is not intended to limit the scope of the claims or the present invention.

An alloy is manufactured by the following well-mixed composites (unit: wt %) obtained by melting a predetermined amount of pure silver and adding a predetermined of pure gold, palladium and calcium:

silver: (94 or more bal.)%, gold: (0.2 to 2)%, palladium: (1 to 5)%, calcium (0.001 to 0.01)%

The wire raw material is obtained by casting the melted mixture into a moulded object and cooling the moulded object. A diameter of the wire raw material is 6 to 10 mm. At this time, a casting condition is 1200° C., a casting speed is 7 cm/min, and a cooling temperature is 20° C.

Subsequently, the final annealing is performed by performing the drawing several times and performing the three intermediate annealing steps.

Firstly, a wire having a diameter of 2 mm is obtained by drawing a wire having a diameter of 6 mm through the first drawing step. At this time, a drawing speed is 10 MPM, and this process is performed about 17 times.

Thereafter, the first intermediate annealing step is performed. The first intermediate annealing step is performed in a batch manner, and the wire is cooled for 90 minutes after the annealing is performed for 60 minutes at 400° C.

The first intermediate annealing step is performed under an Ar condition.

Subsequently, a wire having a diameter reduced to 0.4 mm from 2 mm is obtained through the additional drawing step. At this time, the drawing speed is 30 MPM.

Thereafter, a wire having a diameter reduced to 0.1 mm from 0.4 mm is obtained through the additional drawing step. At this time, the drawing speed is 100 MPM.

Thereafter, a wire having a diameter reduced to 0.05 mm from 0.1 mm is obtained through the additional drawing step. At this time, the drawing speed is 250 MPM.

Subsequently, the second intermediate annealing step is performed. The second intermediate annealing step is performed at 500° C. under 200 rpm in a continuous manner.

After the second intermediate annealing step, a wire having a diameter reduced to 0.03 mm from 0.05 mm is obtained through the additional drawing step. At this time, the drawing speed is 250 MPM.

Thereafter, the third intermediate annealing step is performed. The third intermediate annealing step is performed at 500° C. under 200 rpm in a continuous manner.

Subsequently, a wire having a diameter of 0.7 mil is obtained through a micro drawing step. At this time, the drawing speed is 300 MPM.

Thereafter, the final annealing is finally performed.

### EXPERIMENTAL EXAMPLE

### Checking of Unique Characteristic of Manufactured Wire

The orientation is checked using the wire manufactured in the exemplary embodiment.

The checking is performed using EBSD equipment. It is checked that a ratio of <100>/<111> is 3.3.

It is checked that the number of twin boundaries of the manufactured exemplary embodiment is 9%.

It is checked that a Taylor factor of the manufactured exemplary embodiment is 2.8 and a value of <111>/Taylor factor which is a ratio of the number of the orientations <111> to the Taylor factor is 1.67.

It is checked that the grain size of the manufactured exemplary embodiment is 10 μm.

### EXPERIMENTAL EXAMPLE

### Checking of Performance Characteristic of Manufactured Wire

Various tests are performed using the wire obtained according to the exemplary embodiment of the present invention.

Firstly, the wire is compared with an existing wire using a silver alloy, which is similar to the wire of the exemplary embodiment of the present invention, as a basic material.

An AgUltra product manufactured by Heraeus Holding is used as an existing nano wire.

A comparative measurement value includes data for a bonding characteristic, a looping characteristic and a de-spooling test. A test process which is a standard in a wire bonding field is performed on such properties of the wire.

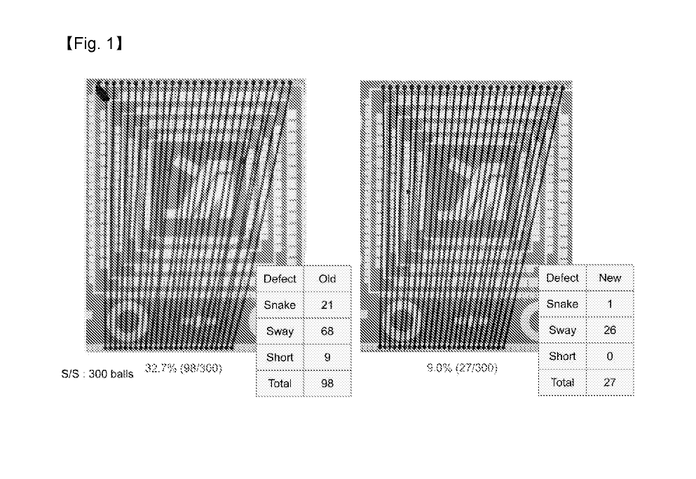

FIG. 1 illustrates data obtained by evaluating the looping characteristic of the bonding wire according to the exemplary embodiment of the present invention. It can be seen that snake, sway and short defects in the exemplary embodiment of the present invention are considerably solved as compared to an existing product.

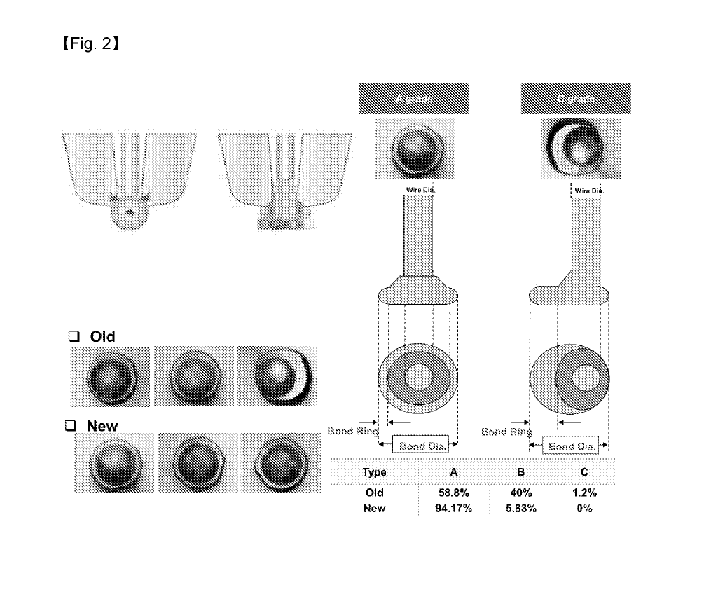

FIG. 2 are photographs obtained by evaluating the bonding characteristic of the bonding wire according to the exemplary embodiment of the present invention.

When ball bonding is performed in a bonding pad by forming FAB (Free air ball) of the wire, a bond diameter in the bonded ball shape needs to be located in the middle of a pad, and lengths of bond rings of sides within the bond diameter need to be constant.

Table 1 represents measurement data of FIG. 2. A is a grade A, and a bond diameter is located in a center of a bonding pad. Further, A means that lengths of bond rings are constantly equal at the respective positions, and it can be seen that many result products of grades A are manufactured by the present invention when compared to the existing product.

TABLE 1

| Type | A | B | C |
|---|---|---|---|
| Old | 58.8% | 40% | 1.2% |
| New | 94.17% | 5.83% | 0% |

Table 2 represents results of a de-spooling test. Specifically, a de-spooling characteristic of the wire is evaluated while free-falling the wire 50 to 70 cm. When unwinding of the wire during the de-spooling stops and the wire is unwound again by a little touch, the number of stopping in the unwinding of the wire is counted, and otherwise, when the wire needs to be deformed, the number of kinks is counted. Table 3 represents evaluated results for 7 days, and it can be seen that the kinks of the exemplary embodiment of the present invention is 10 to 1,000 ppm and a straight characteristic and a sticky characteristic thereof are improved.

TABLE 2

| Comparative Example | Exemplary Embodiment |
|---|---|
| Over 1,000 ppm | Below 1,000 ppm |

The present invention is not limit to the exemplary embodiments, and can be manufactured in various different forms. It should be understood by those skilled in the art that the exemplary embodiments can be implemented in different specific forms without changing the technical spirit and essential feature of the present invention. Therefore, it should be understood that the exemplary embodiments described above are illustrative not restrictive in all aspects.

1.-18. (canceled)

19. A bonding wire comprising: 90.0 to 99.0 wt % of silver (Ag); 0.2 to 2.0 wt % of gold (Au); 0.2 to 4.0 wt % of palladium (Pd), platinum (Pt), rhodium (Rh), or a combination thereof; 10 to 1000 ppm of dopants; and inevitable impurities,
wherein a ratio of (a)/(b) is 3 to 5; wherein
(a) represents an amount of crystal grains having <100> orientation in crystalline orientations <hkl> in a wire lengthwise direction, and
(b) represents an amount of crystal grains having <111> orientation in crystalline orientations <hkl> in the wire lengthwise direction,
wherein the wire is exposed in an intermediate annealing step before a final drawing step of the wire,
wherein the intermediate annealing step includes a first batch intermediate annealing step, a second continuous intermediate annealing step, and a third continuous intermediate annealing step, and
wherein the first intermediate annealing step is performed for 50 to 150 minutes at 400 to 800° C., and includes a step of cooling the wire for 50 to 150 minutes.

20. The bonding wire of claim 19, wherein the dopants are calcium (Ca).

21. The bonding wire of claim 20, wherein a content of the calcium is 10 to 100 ppm.

22. The bonding wire of claim 19, wherein the wire has 4 to 14% twin grain boundaries.

23. The bonding wire of claim 19, wherein a ratio (b)/(c) is 1.5 to 8; wherein
(b) represents an amount of crystal grains having <111> orientation in crystalline orientations <hkl> in a wire lengthwise direction, and
(c) represents a Taylor factor.

24. The bonding wire of claim 19, wherein an average size of the crystal grains in the longitudinal direction is 0.8 to 1.2 μm.

25. The bonding wire of claim 19, wherein the wire is exposed in a casting step by a vertical continuous casting method performed at 1150 to 1350° C.

26. The bonding wire of claim 25, wherein the vertical continuous casting method is performed at a casting speed of 4 to 9 cm/min.

27. A method of manufacturing a bonding wire, comprising:
providing a wire raw material;
casting the wire raw material by a vertical continuous casting method;
drawing the cast wire in sequence until reaching a final diameter; and
annealing the drawn wire,
wherein an intermediate annealing step is performed three times before the final drawing step of the wire, wherein the wire raw material comprises 90.0 to 99.0 wt % of silver (Ag); 0.2 to 2.0 wt % of gold (Au); 0.2 to 4.0 wt % of palladium (Pd), platinum (Pt), rhodium (Rh), or a combination thereof; 10 to 1000 ppm of dopants; and inevitable impurities, and
wherein the intermediate annealing step includes a first batch intermediate annealing step;
a second continuous intermediate annealing step; and a third continuous intermediate annealing step.

28. The method of manufacturing a bonding wire of claim 27, wherein the dopants are calcium and a content of the calcium is 10 to 100 ppm.

29. The method of manufacturing a bonding wire of claim 27, wherein the first intermediate annealing step is performed for 50 to 150 minutes at 400 to 800° C. and includes a step of cooling the wire for 50 to 150 minutes.

30. The method of manufacturing a bonding wire of claim 27, wherein the second intermediate annealing step and the third intermediate annealing step have the same process conditions.

31. The method of manufacturing a bonding wire of claim 27, wherein the vertical continuous casting method is performed at 1150 to 1350° C.

32. The method of manufacturing a bonding wire of claim 31, wherein the vertical continuous casting method is performed under a casting speed of 4 to 9 cm/min.

33. The method of manufacturing a bonding wire of claim 27, wherein a ratio of (a)/(b) of the bonding wire manufactured by the method is 3 to 5; wherein
(a) represents an amount of crystal grains having <100> orientation in crystalline orientations <hkl> in a wire lengthwise direction, and
(b) represents an amount of crystal grains having <111> orientation in crystalline orientations <hkl> in a wire lengthwise direction.

34. The method of manufacturing a bonding wire of claim 27, wherein a number of twin grain boundaries of the bonding wire is 4 to 14%.

35. The method of manufacturing a bonding wire of claim 27, wherein a ratio (b)/(c) of the bonding wire is 1.5 to 8, wherein (b) represents an amount of crystal grains having <111> orientation in crystalline orientations <hkl> in a wire lengthwise direction, and (c) represents a Taylor factor.

36. The method of manufacturing a bonding wire of claim 27, wherein an average size of crystal grains of the bonding wire in a longitudinal direction is 0.8 to 1.2 μm.
